(19) United States
(12) Patent Application Publication
(10) Pub. No.: US 2017/0361712 A1
(43) Pub. Date: Dec. 21, 2017

(54) ELECTRIC VEHICLE

(71) Applicant: TOYOTA JIDOSHA KABUSHIKI KAISHA, Toyota-shi (JP)

(72) Inventors: Yasuhiro TERAO, Okazaki-shi (JP); Koichi SAKATA, Okazaki-shi (JP)

(73) Assignee: TOYOTA JIDOSHA KABUSHIKI KAISHA, Toyota-shi (JP)

(21) Appl. No.: 15/490,273

(22) Filed: Apr. 18, 2017

(30) Foreign Application Priority Data
Jun. 15, 2016 (JP) 2016-118910

(51) Int. Cl. B60L 3/00; H03K 17/687; B60K 6/445

(52) U.S. Cl. CPC B60L 3/0007; H03K 17/6872; B60L 3/0046; B60K 6/445; Y10S 903/903

(57) ABSTRACT

An electric vehicle includes: a motor configured to drive a wheel; a smoothing capacitor provided within a power supply circuit that supplies electric power to the motor; a processor configured to perform a discharge process when the electric vehicle crashes, the discharge process discharging the smoothing capacitor by controlling the power supply circuit; a power source connected to each of a plurality of electric loads including the processor via a corresponding fuse; a relay circuit electrically connected between the power source and the processor and configured to be driven to electrically connect between the power source and the processor in response to a relay drive signal outputted from the processor; and a holding circuit configured to temporarily hold the relay circuit in a driven state when the processor quits outputting the relay drive signal.

### TECHNICAL FIELD

The disclosure herein relates to an electric vehicle. The electric vehicle herein referred to generally means an automobile that has a motor configured to drive a wheel. The electric vehicle includes, but is not particularly limited to: a rechargeable electric vehicle recharged with external electric power; a fuel cell vehicle that has a fuel cell; a solar cell vehicle that has a solar cell; a hybrid vehicle that further has an engine; and an automobile that has two or more of these features.

### BACKGROUND

The electric vehicle has been known. The electric vehicle has a motor that drives a wheel. In a power supply circuit that supplies electric power to the motor, a smoothing capacitor can be provided in addition to a DC-DC converter or an inverter, for example. The smoothing capacitor stores electrical charges to thereby restrain fluctuations in voltage within the power supply circuit. While the electric vehicle is used, electrical charges are stored in the smoothing capacitor at a high voltage. Accordingly, when the electric vehicle crashes, the smoothing capacitor is required to be quickly discharged.

To discharge the smoothing capacitor, the electric vehicle can further include a processor that performs a discharge process. The discharge process is a process of, when the electric vehicle crashes, discharging the smoothing capacitor by controlling the power supply circuit. For example, the processor can discharge the smoothing capacitor through the motor by controlling an inverter circuit. In this case, the processor can adjust a current that flows in the motor such that an output torque of the motor becomes zero. Such control is referred to as zero torque control. One example of the art described above is described in Japanese Patent Application Publication No. 2006-141158.

### SUMMARY

The electric vehicle may further include a power source and a relay circuit. The power source may be an accessory battery, for example, and is electrically connected to each of a plurality of electric loads including the processor via a corresponding fuse. The relay circuit is electrically connected between the power source and the processor, and is driven to electrically connect between the power source and the processor in response to a relay drive signal outputted from the processor. According to such a configuration, when the processor quits its operation, for example, the processor can quit outputting the relay drive signal, to thereby electrically disconnect between itself and the power source.

When the electric vehicle crashes, a conductive path (e.g., a wire harness) that connects the power source and any of the electric loads, or the electric load itself may be damaged, which may cause a short circuit in the power source. In this case, a corresponding fuse is blown to thereby quickly resolve the short circuit in the power source, and electric power supply to the other electric loads is resumed. However, an output voltage of the power source temporarily decreases during a period from the occurrence of a short circuit to the blowout of the fuse, and hence there may be a case where the processor quits its operation. If the processor quits its operation, the output of the relay drive signal by the processor is also quitted, and the driving of the relay circuit is also quitted. Consequently, the power source and the processor are electrically disconnected. In this case, even if the output voltage of the power source is subsequently recovered, there may be a case where the processor cannot be activated again and cannot discharge the smoothing capacitor.

The present disclosure provides a technique capable of activating the processor again when the output voltage of the power source temporarily decreases and the processor quits its operation.

An electric vehicle disclosed herein may comprise: a motor configured to drive a wheel; a smoothing capacitor provided within a power supply circuit that supplies electric power to the motor; a processor configured to perform a discharge process when the electric vehicle crashes, the discharge process discharging the smoothing capacitor by controlling the power supply circuit; a power source connected to each of a plurality of each of electric loads including the processor via a corresponding fuse; a relay circuit electrically connected between the power source and the processor and configured to be driven to electrically connect between the power source and the processor in response to a relay drive signal outputted from the processor; and a holding circuit configured to temporarily hold the relay circuit in a driven state when the processor quits outputting the relay drive signal.

In this electric vehicle as well, when the above-mentioned short circuit in the power source occurs, there may be a ease where the processor quits its operation owing to a temporary decrease in the output voltage of the power source. When the processor quits its operation, the output of the relay drive signal from the processor is also quitted. However, even if the processor quits outputting the relay drive signal, the holding circuit temporarily holds the relay circuit in a driven state. Meanwhile, if the output voltage of the power source is recovered, the processor can be activated again and resume outputting the relay drive signal. Then the processor can discharge the smoothing capacitor by performing the discharge process.

### BRIEF DESCRIPTION OF DRAWINGS

FIG. 1 is a block diagram that schematically shows a configuration of a hybrid vehicle 10;

FIG. 2 schematically shows an internal configuration of a power supply circuit 32;

FIG. 3 schematically shows an internal configuration of a motor control unit 44;

FIG. 4 shows one example of a time chart according to a discharge process by a processor 62;

FIG. 5 shows one example of a short circuit that occurs in an accessory battery 34;

FIG. 6 shows one example of a time chart according to the discharge process by the processor 62 in a case where the accessory battery 34 is short-circuited;

FIG. 7 schematically shows an internal configuration of a motor control unit 144 in a variation;

FIG. 8 shows one example of a time chart according to the discharge process by the processor 62 in the variation. In FIGS. 4, 6, and 8, the same signs indicate the same or corresponding indices; and

FIG. 9 schematically shows an internal configuration of a motor control unit 244 in another variation.

### DETAILED DESCRIPTION

Representative, non-limiting examples of the present invention will now be described in further detail with reference to the attached drawings. This detailed description is merely intended to teach a person of skill in the art further details for practicing preferred aspects of the present teachings and is not intended to limit the scope of the invention. Furthermore, each of the additional features and teachings disclosed below may be utilized separately or in conjunction with other features and teachings to provide improved electric vehicles, as well as methods for using and manufacturing the same.

Moreover, combinations of features and steps disclosed in the following detailed description may not be necessary to practice the invention in the broadest sense, and are instead taught merely to particularly describe representative examples of the invention. Furthermore, various features of the above-described and below-described representative examples, as well as the various independent and dependent claims, may be combined in ways that are not specifically and explicitly enumerated in order to provide additional useful embodiments of the present teachings.

All features disclosed in the description and/or the claims are intended to be disclosed separately and independently from each other for the purpose of original written disclosure, as well as for the purpose of restricting the claimed subject matter, independent of the compositions of the features in the embodiments and/or the claims. In addition, all value ranges or indications of groups of entities are intended to disclose every possible intermediate value or intermediate entity for the purpose of original written disclosure, as well as for the purpose of restricting the claimed subject matter.

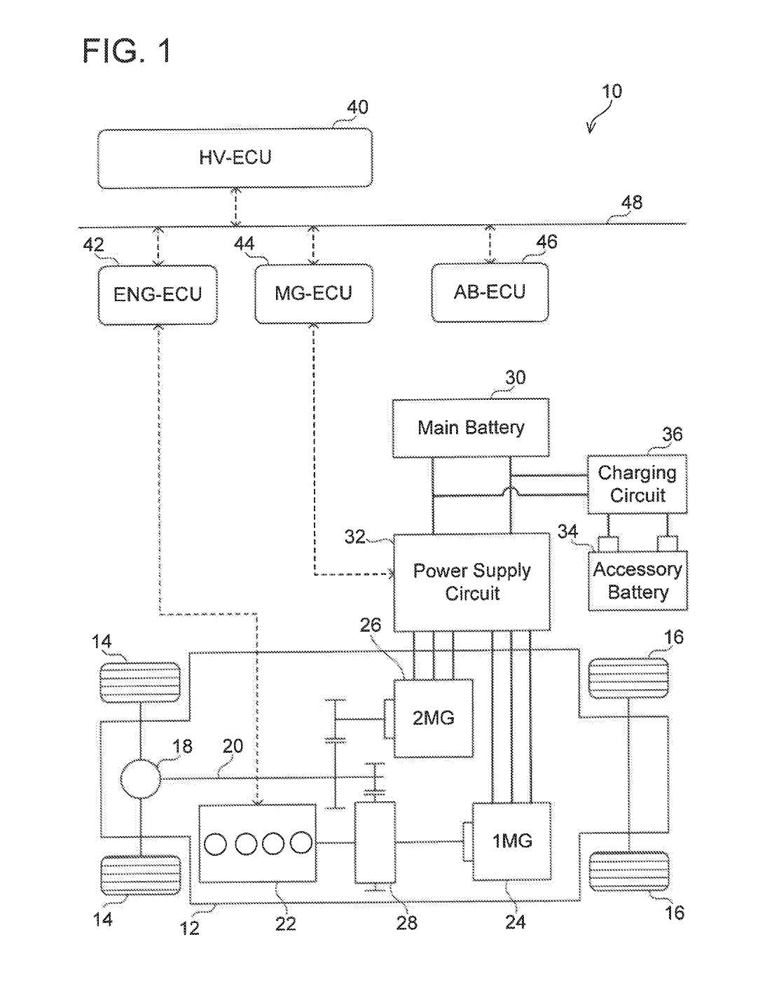

A hybrid vehicle 10 in one embodiment will be described with reference to the drawings. The hybrid vehicle 10 is one example of an electric vehicle disclosed herein. The configuration of the hybrid vehicle 10 described below can also be applied to other types of electric vehicles. As shown in FIG. 1, the hybrid vehicle 10 in the present embodiment includes a vehicle body 12, and four wheels 14 and 16 supported rotatably relative to the vehicle body 12. The four wheels 14 and 16 include a pair of driving wheels 14 and a pair of driven wheels 16. The pair of driving wheels 14 is connected to an output shaft 20 via a differential gear 18. The output shaft 20 is supported rotatably relative to the vehicle body 12. As one example, the pair of driving wheels 14 is rear wheels positioned at a rear portion of the vehicle body 12, while the pair of driven wheels 16 is front wheels positioned at a front portion of the vehicle body 12. The pair of driving wheels 14 is disposed coaxially with each other, and the pair of driven wheels 16 is also disposed coaxially with each other.

The hybrid vehicle 10 further includes an engine 22, a first motor generator 24 (1MG in the drawing), and a second motor generator 26 (2MG in the drawing). The engine 22 combusts fuel such as gasoline, and outputs power. Each of the first and second motor generators 24 and 26 is a three-phase motor generator that has a U phase, a V phase and a W phase. In the following, the first motor generator 24 is simply referred to as the first motor 24, and the second motor generator 26 is simply referred to as the second motor 26. The engine 22 is connected to the output shaft 20 and the first motor 24 via a power distribution mechanism 28. The power distribution mechanism 28 distributes the power outputted by the engine 22, to the output shaft 20 and the first motor 24. As one example, the power distribution mechanism 28 in the present embodiment has a planetary gear mechanism. The second motor 26 is connected to the output shaft 20. With such a configuration, the first motor 24 functions as a generator driven by the engine 22. Moreover, the first motor 24 also functions as a starter motor for starting the engine 22. On the other hand, the second motor 26 primarily functions as a motor that drives the pair of driving wheels 14. Moreover, the second motor 26 also functions as a generator when the hybrid vehicle 10 carries out regenerative braking.

The hybrid vehicle 10 further includes a main battery 30 and a power supply circuit 32. The main battery 30 is electrically connected to the first and second motors 24 and 26 via the power supply circuit 32. The main battery 30 is a rechargeable battery, and although no particular limitation is imposed on the main battery 30, it has a plurality of lithium-ion cells. The power supply circuit 32 supplies electric power from the main battery 30 to each of the first and second motors 24 and 26. Moreover, the power supply circuit 32 supplies electric power generated at the first motor 24 or the second motor 26 to the main battery 30. As one example, the main battery 30 in the present embodiment has a rated voltage of approximately 200 volts, and each of the first and second motors 24 and 26 has a rated voltage of approximately 600 volts. In other words, the main battery 30 has a rated voltage lower than that of each of the first and second motors 24 and 26. It should be noted that no particular limitation is imposed on specific values of rated voltages of the main battery 30, the first motor 24, and the second motor 26, or on a relation in magnitude among the rated voltages.

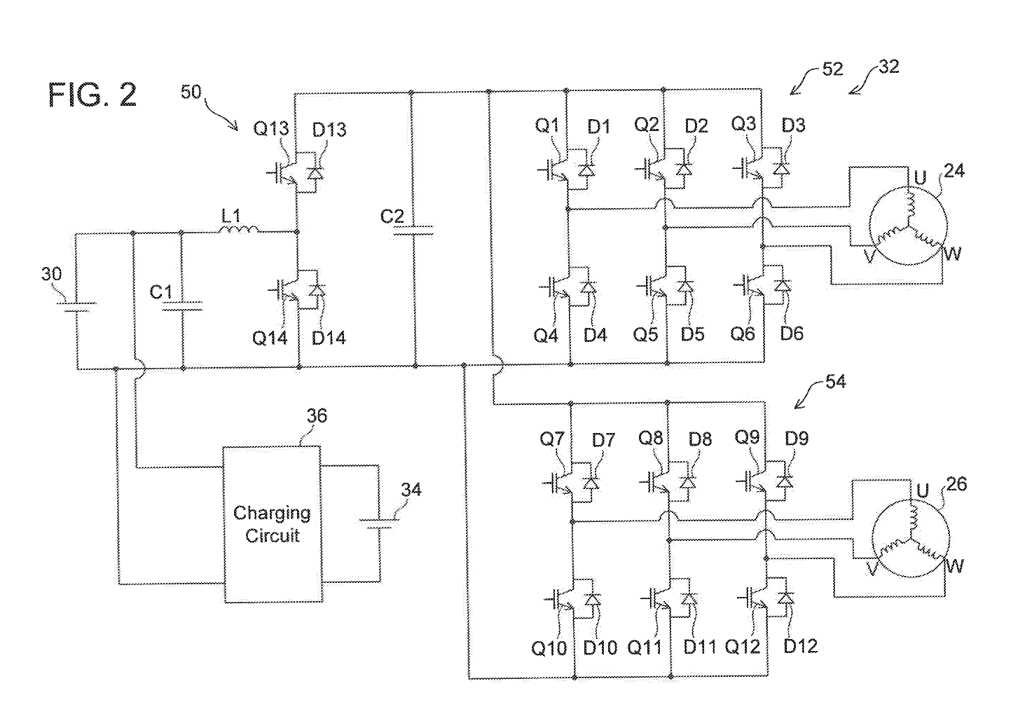

As shown in FIG. 2, the power supply circuit 32 includes a DC-DC converter 50, a first inverter 52, and a second inverter 54. The DC-DC converter 50 is a DC-DC converter that enables step-up and step-down of voltage. As one example, the DC-DC converter 50 includes an inductor L1, an upper arm switching element Q13, a lower arm switching element Q14, an upper arm diode D13, and a lower arm diode D14. The DC-DC converter intermittently turns on the lower arm switching element Q14, to thereby function as a step-up converter. Moreover, the DC-DC converter intermittently turns on the upper arm switching element Q13, to thereby function as a step-down converter.

The first inverter 52 has a plurality of switching elements Q1 to Q6, and a plurality of diodes D1 to D6. Each of the plurality of diodes D1 to D6 is connected in parallel with corresponding one of the plurality of switching elements Q1 to Q6. The first inverter 52 selectively turns on and off the plurality of switching elements Q1 to Q6, to thereby convert the DC electric power from the DC-DC converter 50 into AC electric power. Similarly, the second inverter 54 has a plurality of switching elements Q7 to Q12, and a plurality of diodes D7 to D12. Each of the plurality of diodes D7 to D12 is connected in parallel with corresponding one of the plurality of switching elements Q7 to Q12. The second inverter 54 selectively turns on and off the plurality of switching elements Q7 to Q12, to thereby convert the DC electric power from the DC-DC converter 50 into AC electric power.

The main battery 30 is connected to the first motor 24 via the DC-DC converter 50 and the first inverter 52. If the first motor 24 functions as a motor, the DC electric power from the main battery 30 is stepped up in voltage in the DC-DC converter 50, subsequently converted into AC electric power in the first inverter 52, and then supplied to the first motor 24. On the other hand, if the first motor 24 functions as a generator, the AC electric power from the first motor 24 is converted into DC electric power in the first inverter 52, next, stepped down in voltage in the DC-DC converter 50, and then supplied to the main battery 30.

Similarly, the main battery 30 is connected to the second motor 26 via the DC-DC converter 50 and the second inverter 54. If the second motor 26 functions as a motor, the DC electric power from the main battery 30 is stepped up in voltage in the DC-DC converter 50, next, converted into AC electric power in the second inverter 54, and then supplied to the second motor 26. On the other hand, if the second motor 26 functions as a generator, the AC electric power from the second motor 26 is converted into DC electric power in the second inverter 54, next, stepped down in voltage in the DC-DC converter 50, and then supplied to the main battery 30. It should be noted that the configuration of the power supply circuit 32 in the present embodiment is one example, and can be changed as appropriate in accordance with the configuration of each of the main battery 30, the first motor 24, and the second motor 26. For example, if the main battery 30 has the same rated voltage as that of each of the first and second motors 24 and 26, the DC-DC converter 50 is not necessarily required.

The power supply circuit 32 further includes a first smoothing capacitor C1 and a second smoothing capacitor C2. The first smoothing capacitor C1 is positioned between the main battery 30 and the DC-DC converter 50, and the second smoothing capacitor C2 is positioned between the DC-DC converter 50 and the first inverter 52, and between the DC-DC converter 50 and the second inverter 54. Each of the first and second smoothing capacitors C1 and C2 stores electrical charges, to thereby restrain fluctuations in voltage within the power supply circuit 32. For example, the first smoothing capacitor C1 restrains fluctuations in the DC voltage outputted from the DC-DC converter 50 to the main battery 30. Moreover, the second smoothing capacitor C2 restrains fluctuations in the DC voltage outputted from the DC-DC converter 50 to the first and second inverters 52 and 54. It should be noted that the power supply circuit 32 may include only one of the first and second smoothing capacitors C1 and C2, or may further include another smoothing capacitor. The number and positions of the smoothing capacitors can be changed as appropriate in accordance with the configuration of the power supply circuit 32.

Returning to FIG. 1, the hybrid vehicle 10 further includes a hybrid control unit 40 (HV-ECU in the drawing), an engine control unit 42 (ENG-ECU in the drawing), a motor control unit 44 (MG-ECU in the drawing), and an air bag control unit 46 (AB-ECU in the drawing). The engine control unit 42 is communicatively connected to the engine 22, and controls an operation of the engine 22. The motor control unit 44 is communicatively connected to the power supply circuit 32, and controls an operation of the power supply circuit 32. Specifically, the motor control unit 44 controls the switching elements Q1 to Q14 in the power supply circuit 32, to thereby control an operation of each of the first and second motors 24 and 26. The hybrid control unit 40 can communicate with a plurality of control units including the engine control unit 42, the motor control unit 44, and the air bag control unit 46, via a communication path 48, and gives them an operation command to thereby control the entire operation of the hybrid vehicle 10.

The air bag control unit 46 controls an operation of one or more air bags (not shown) provided in the hybrid vehicle 10. The air bag control unit 46, in particular, has an acceleration sensor, for example, and can detect a crash of the hybrid vehicle 10. When detecting a crash of the hybrid vehicle 10, the air bag control unit 46 operates the air bag(s). Moreover, when detecting a crash of the hybrid vehicle 10, the air bag control unit 46 transmits a prescribed crash signal to the plurality of control units including the hybrid control unit 40 and the motor control unit 44. As one example, the crash signal may be a train of pulse signals with prescribed periodicity. Notably, the hybrid vehicle 10 may include another crash detection device that detects a crash of the hybrid vehicle 10, in place of, or in addition to the air bag control unit 46.

As shown in FIGS. 1 and 2, the hybrid vehicle 10 further includes an accessory battery 34 and a charging circuit 36. The accessory battery 34 is electrically connected to the main battery 30 via the charging circuit 36. The accessory battery 34 is a power source that supplies electric power to the plurality of electric loads mounted on the hybrid vehicle 10, including the motor control unit 44, for example. As one example, the accessory battery 34 has a rated voltage of 12 volts. The accessory battery 34 is a rechargeable battery, and charged with electric power supplied from the main battery 30. The charging circuit 36 has a step-down-type DC-DC converter, and steps down the DC voltage from the main battery 30 to a DC voltage suitable for charging of the accessory battery 34, to thereby charge the accessory battery 34.

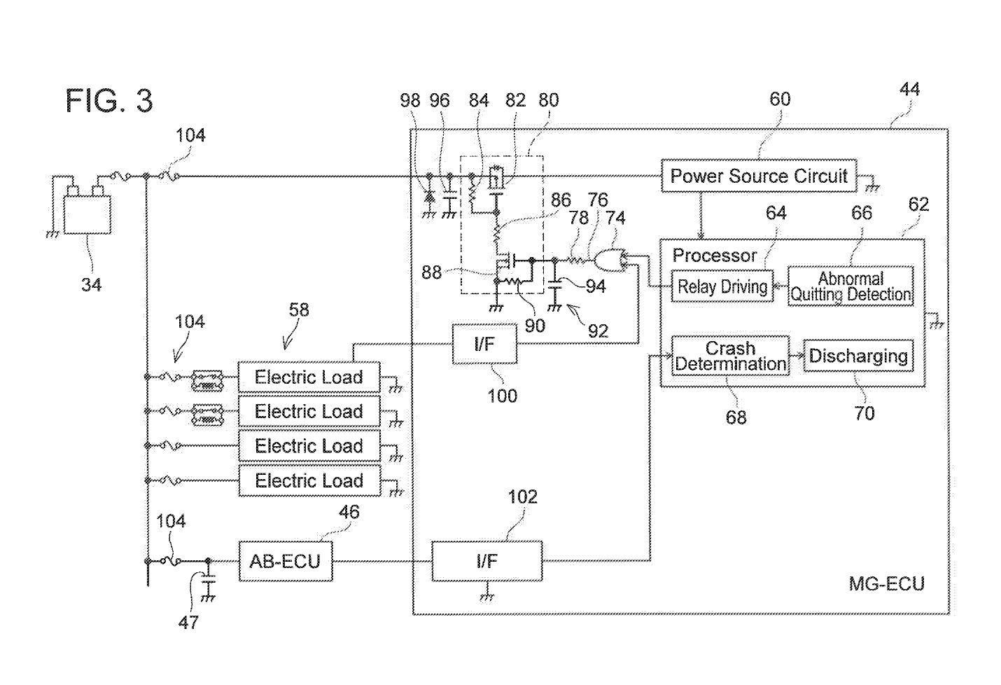

As shown in FIG. 3, the accessory battery 34 is electrically connected to the plurality of electric loads including the motor control unit 44 via the corresponding fuses 104. It should be noted that the plurality of electric loads also include the air bag control unit 46 and other electric loads 58. It should be noted that other electric loads 58 shown in FIG. 3 include the hybrid control unit 40 and the engine control unit 42, which have been mentioned above, for example. The air bag control unit 46 is provided with a first back-up power source 47. The first back-up power source 47 has a rechargeable power storage element (e.g., a capacitor or a secondary battery), and is charged by the accessory battery 34. When the electric power supply from the accessory battery 34 to the air bag control unit 46 is stopped, the first back-up power source 47 substitutes for the accessory battery 34 and supplies electric power to the air bag control unit 46. This enables the air bag control unit 46 to continue its operation for a prescribed time even when the corresponding fuse 104 between the accessory battery 34 and the air bag control unit 46 is blown, for example.

As shown in FIG. 3, the motor control unit 44 includes a power source circuit 60 and a processor 62. The processor 62 is electrically connected to the accessory battery 34 via the power source circuit 60, and operates by the electric power supplied from the accessory battery 34. A corresponding fuse 104 and a relay circuit 80, which will be mentioned below, are electrically intervened between the power source circuit 60 and the accessory battery 34. The power source circuit 60 adjusts the voltage inputted from the accessory battery 34 to a voltage corresponding to the rated voltage of the processor 62. As one example, the power source circuit 60 in the present embodiment adjusts a voltage of 12 volts inputted from the accessory battery 34 to 5 volts, and outputs the adjusted voltage. The processor 62 has a CPU and a memory, and can use a plurality of programs and a plurality of parameters stored in the memory to perform a plurality of processes. As schematically shown in FIG. 3, the plurality of processes includes a relay driving process 64, an abnormal quitting detection process 66, a crash determination process 68, and a discharge process 70. Moreover, although not shown, the processor 62 can perform a process of controlling an operation of the power supply circuit 32, based on an operation command by the hybrid control unit 40 (e.g., a target torque of each of the first and second motors 24 and 26). For this purpose, the motor control unit 44 may further include at least one processor in addition to the processor 62 shown in FIG. 3.

The crash determination process 68 is a process of determining whether or not the hybrid vehicle 10 has crashed based on the crash signal outputted from the air bag control unit 46. To the processor 62, the crash signal outputted from the air bag control unit 46 is inputted via an interface circuit 102. The discharge process 70 is a process of; when the crash determination process 68 determines that the hybrid vehicle 10 has crashed, discharging the first and second smoothing capacitors C1 and C2 by controlling the power supply circuit 32. As one example, in this discharge process 70, it is possible to discharge the first and second smoothing capacitors C1 and C2 through the second motor 26 by controlling the DC-DC converter 50 and the second inverter 54. In this case, the current that flows in the second motor 26 may be preferably adjusted such that the output torque of the second motor 26 becomes zero. In other words, the zero torque control on the second motor 26 is preferably performed. Notably, in other embodiments, if the power supply circuit 32 has another circuit structure that can discharge the first and second smoothing capacitors C1 and C2, that circuit structure may be utilized in the discharge process 70. Notably, when the discharge process 70 is performed, the main battery 30 is electrically disconnected from the power supply circuit 32 by a switch or a relay, not shown. The relay driving process 64 and the abnormal quitting detection process 66 will be described later.

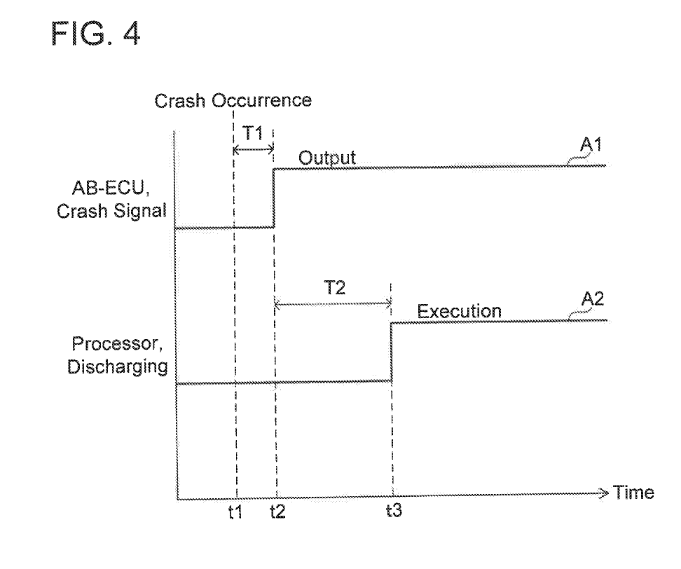

By performing the crash determination process 68 and the discharge process 70, the processor 62 can discharge the first and second smoothing capacitors C1 and C2 in the power supply circuit 32 when the hybrid vehicle 10 crashes. As shown in FIG. 4, assume that the hybrid vehicle 10 crashes at a time point t1, for example. In this case, at a time point t2, the air bag control unit 46 starts outputting the crash signal (see A1 in the drawing). A time T1 from the time point t1 to the time point t2 represents a processing time necessary for the air bag control unit 46 to detect the crash. When the air bag control unit 46 starts outputting the crash signal, the processor 62 starts the discharge process 70 at a time point t3 (see 42 in the drawing). A time T2 from the time point t2 to the time point t3 is a time necessary for the processor 62 to perform the crash determination process 68. To avoid erroneous determination caused by a noise signal, the processor 62 determines that the hybrid vehicle 10 has crashed when the processor 62 keeps receiving the crash signal for the time T2. As one example, in the present embodiment, a design value of the time T1 is 50 milliseconds, and a design value of the time T2 is 180 milliseconds.

Returning to FIG. 3, the motor control unit 44 further includes the relay circuit 80. The relay circuit 80 is electrically connected between the accessory battery 34 and the power source circuit 60. The relay circuit 80 is driven to electrically connect between the accessory battery 34 and the power source circuit 60 in response to a relay drive signal outputted from the processor 62. In other words, while the processor 62 is outputting the relay drive signal, the accessory battery 34 and the processor 62 are electrically connected, and electric power is supplied from the accessory battery 34 to the processor 62. On the other hand, when the processor 62 quits its operation, the processor 62 quits outputting the relay drive signal, and interrupts, by itself, the electric power supply from the accessory battery 34. The relay drive signal in the present embodiment is a signal having a prescribed DC voltage (e.g., 3 to 5 volts). The motor control unit 44 may further include a diode 98 for circuit protection, and a capacitor 96 for noise prevention.

No particular limitation is imposed on the specific configuration of the relay circuit 80. As one example, the relay circuit 80 in the present embodiment has a p channel-type field-effect transistor 82 (hereinafter p-FET 82) and an n channel-type field-effect transistor 88 (hereinafter n-FET 88). A source of the p-FET 82 is electrically connected to the accessory battery 34, and a drain of the p-FET 82 is electrically connected to the power source circuit 60. The p-FET 82 can thereby be electrically connected and disconnected between the accessory battery 34 and the power source circuit 60, A gate and the source of the p-FET 82 are electrically connected via a resistor 84. The gate of the p-FET 82 is electrically connected to a drain of the n-FET 88 via a resistor 86. A source of the n-FET 88 is electrically grounded, and a gate and the source of the n-FET 88 are electrically connected via a resistor 90. The relay drive signal is then inputted to the gate of the n-FET 88. With such a configuration, when the processor 62 outputs the relay drive signal, the n-FET 88 and the p-PET 82 are turned on, causing the accessory battery 34 and the processor 62 to be electrically connected. In other words, the relay drive signal has a DC voltage higher than a threshold voltage of the n-FET 88. When the processor 62 then quits outputting the relay drive signal, the n-FET 88 and the p-FET 82 are turned off, causing the accessory battery 34 and the processor 62 to be electrically disconnected.

The relay drive signal outputted by the processor 62 is inputted to the relay circuit 80 through a signal path 76. Here, the signal path 76 is provided with an OR circuit 74 and a resistor 78. To the OR circuit 74, a relay activation signal outputted from one of other electric loads 58 (e.g., the hybrid control unit 40) is inputted via an interface circuit 100, in addition to the relay drive signal. Usually, when the processor 62 is to be activated, the relay circuit 80 is driven by the relay activation signal outputted from one of other electric loads 58. This starts the electric power supply from the accessory battery 34 to the processor 62, causing the processor 62 to be activated. After the processor 62 is activated, the processor 62 starts outputting the relay drive signal, and the relay circuit 80 is maintained in a driven state. Here, no particular limitation is imposed on the configuration of the OR circuit 74, and the OR circuit 74 may be configured with use of an integrated circuit, or may be a discrete circuit that has one or more semiconductor elements. Notably, in other embodiments, a second path for supplying electric power from the accessory battery 34 to the processor 62 may separately be provided. In this case, a second relay circuit may be provided on the second path, and a relay activation signal outputted from one of other electric loads 58 (e.g., the hybrid control unit 40) may be configured to be inputted to the second relay circuit. According to such a configuration, when the processor 62 is to be activated, electric power is supplied from the accessory battery 34 to the processor 62 via the second path. Accordingly, the OR circuit 74 is not required.

The motor control unit 44 further includes a holding circuit 92. The holding circuit 92 is connected to the signal path 76. The holding circuit 92 is configured to temporarily hold the relay circuit 80 in a driven state when the processor 62 quits outputting the relay drive signal.

The holding circuit 92 in the present embodiment has a power storage element 94. This power storage element 94 is a capacitor, but the power storage element 94 may be a secondary battery or another power storage element. The power storage element 94 has one end electrically connected to the signal path 76, and the other end electrically grounded. The processor 62 is also electrically grounded, and hence the processor 62 and the power storage element 94 are connected in parallel with each other with respect to the relay circuit 80. More specifically, the processor 62 and the power storage element 94 are connected in parallel with each other with respect to an input portion of the relay circuit 80 to which the relay drive signal is inputted.

As mentioned above, the relay drive signal outputted by the processor 62 is a signal having a prescribed DC voltage. Accordingly, while the processor 62 is outputting the relay drive signal, the power storage element 94 is charged by the relay drive signal. Even if the processor 62 quits outputting the relay drive signal, the power storage element 94 thus charged inputs a voltage equivalent to or corresponding to the relay drive signal to the relay circuit 80. This enables the relay circuit 80 to be temporarily held in a driven state even after the processor 62 quits outputting the relay drive signal. The resistor 90 in the relay circuit 80 is connected in parallel with the power storage element 94. Accordingly, the power storage element 94 is gradually discharged via the resistor 90, causing the relay circuit 80 to be turned off eventually. The time during which the power storage element 94 holds the relay circuit 80 in a driven state can be adjusted by means of a capacity of the power storage element 94 and a resistance value of the resistor 90.

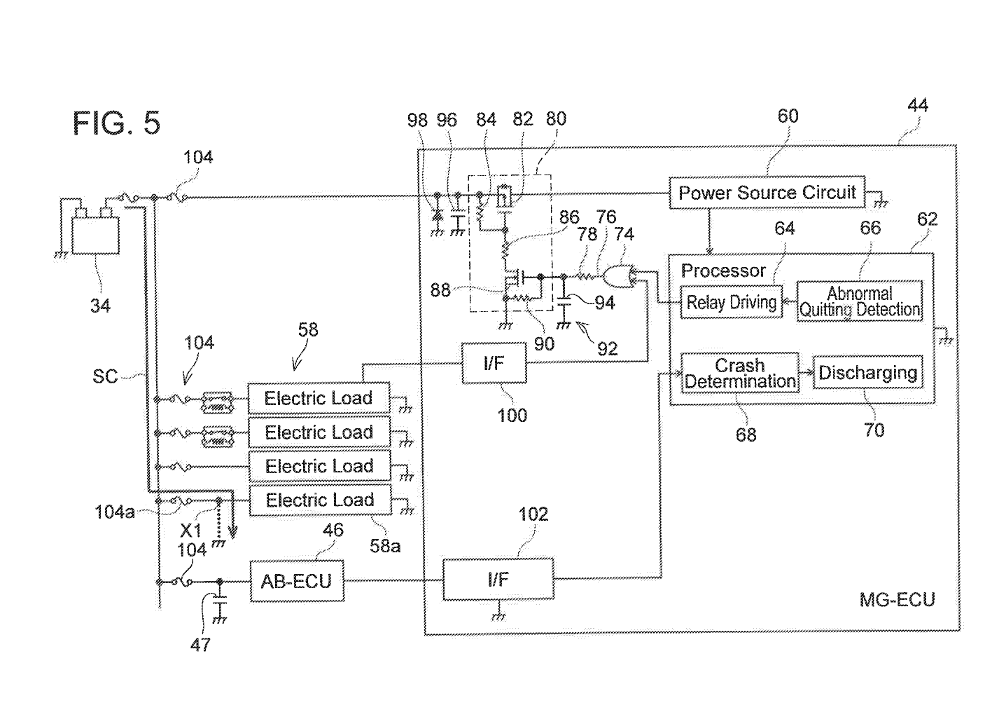

As mentioned above, in the hybrid vehicle 10 in the present embodiment, when the hybrid vehicle 10 crashes, the first and second smoothing capacitors C1 and C2 in the power supply circuit 32 can be discharged. However, when the hybrid vehicle 10 crashes, there may be a case where the vehicle body 12 is significantly deformed, for example, to thereby cause a short circuit in the accessory battery 34. As shown in FIG. 5, for example, assume that a wire harness X1 that electrically connects the accessory battery 34 and one electric load 58a is damaged and brought into contact with the vehicle body 12, to thereby be electrically grounded. In this case, the accessory battery 34 is short-circuited, to thereby generate a large short circuit current SC. It should be noted that, owing to a blowout of the fuse 104a, the short circuit in the accessory battery 34 is quickly resolved, and electric power supply to the other electric loads including the motor control unit 44 is resumed.

However, during a period from the occurrence of the short circuit to the blowout of the fuse 104a, the output voltage of the accessory battery 34 temporarily decreases. Consequently, there may be a case where the supply voltage to the processor 62 also decreases, and the processor 62 quits its operation. When the processor 62 quits its operation, the output of the relay drive signal by the processor 62 is also quitted. At this time, if the motor control unit 44 does not include the holding circuit 92, the driving of the relay circuit 80 is disadvantageously stopped unless a relay activation signal is provided by the interface circuit 100. In this case, even if the output voltage of the accessory battery 34 is subsequently recovered, the processor 62 cannot receive electric power supply from the accessory battery 34. The processor 62 can neither be activated again nor perform the discharge process 70.

In contrast to the above, the motor control unit 44 in the present embodiment includes the holding circuit 92, and even if the processor 62 quits outputting the relay drive signal, the holding circuit 92 temporarily holds the relay circuit 80 in a driven state. Meanwhile, if the output voltage of the accessory battery 34 is recovered, the accessory battery 34 is electrically connected to the processor 62, enabling the processor 62 to be activated again and resume outputting the relay drive signal. Then the processor 62 can discharge the first and second smoothing capacitors C1 and C2 by performing the crash determination process 68 and the discharge process 70. As such, according to the hybrid vehicle 10 in the present embodiment, When the hybrid vehicle 10 crashes, the first and second smoothing capacitors C1 and C2 can more reliably be discharged.

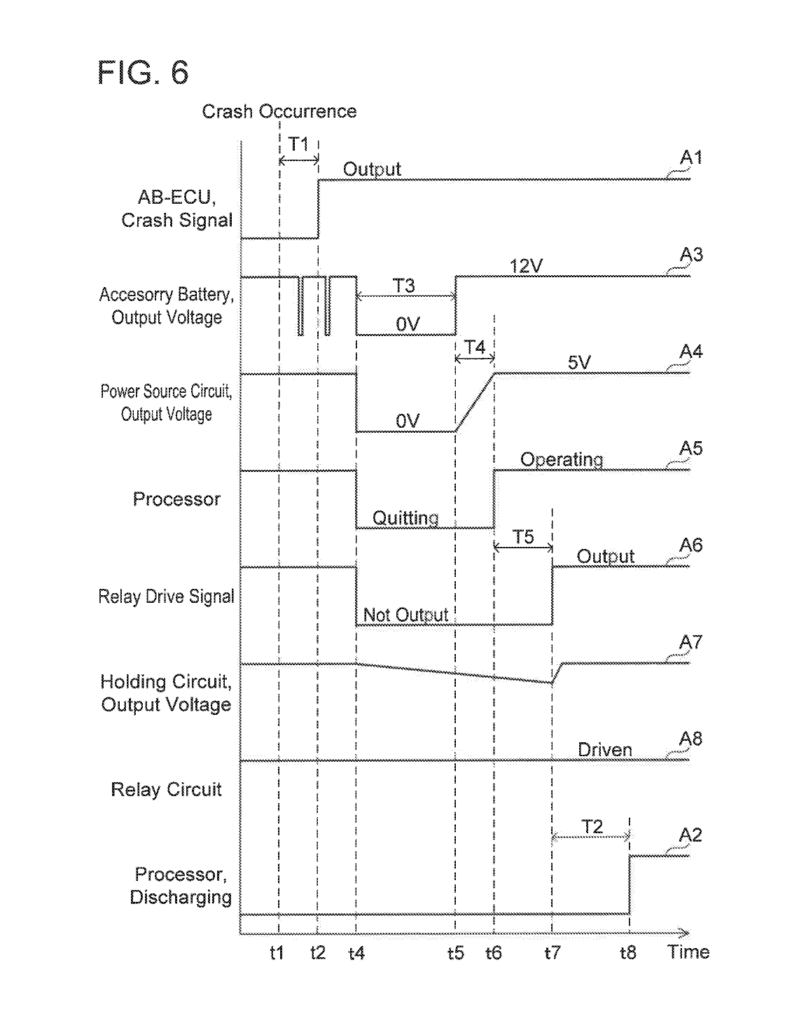

With reference to FIG. 6, a specific example of a series of the flows described above will be described. Similarly to the example in FIG. 4, when the hybrid vehicle 10 crashes at the time point t1, the air bag control unit 46 starts outputting the crash signal at the time point t2 (see A1 in the drawing). Assume that a short circuit occurs one or more times in the accessory battery 34, mentioned above, after the time point 11, and the output voltage of the accessory^{,} battery 34 decreases to approximately zero volt for a time T3 from a time point t4 to a time point t5 (see A3). In this case, at the time point t4, the output voltage of the power source circuit 60 also decreases to approximately zero volt (see A4), thereby causing the processor 62 to quit its operation (see A5). Accordingly, the output of the relay drive signal is quitted (see A6). At this stage, however, the power storage element 94 in the holding circuit 92 is charged, and hence by the output voltage of the holding circuit 92 (see A7), the relay circuit 80 is maintained in a driven state even after the time point t4 (see A8).

Afterwards, when the output voltage of the accessory battery 34 is recovered to 12 volts at the time point t5, the output voltage of the power source circuit 60 is also recovered to 5 volts at a time point t6, and the processor 62 is activated again. In other words, even at the time point t6, the holding circuit 92 holds the relay circuit 80 in a driven state, and electric power supply from the accessory battery 34 to the processor 62 is resumed. A time T4 from the time point t5 to the time point t6 is a time necessary for the output voltage of the power source circuit 60 to reach 5 volts, which is a target voltage, by feedback control within the power source circuit 60.

When the processor 62 is activated again at the time point t6, the processor 62 carries out a prescribed initialization process, and subsequently performs the abnormal quitting detection process 66 (see FIG. 3). The abnormal quitting detection process 66 is a process of detecting whether or not the last quitting of operation of the processor 62 is abnormal. The abnormal quitting of operation herein referred to includes quitting of operation due to a loss of power source electric power, as occurring at the time point t4. The memory of the processor 62 records an operation history of the processor 62, and in the abnormal quitting detection process 66, the operation history is referenced. For example, if no normal quitting of operation is recorded at the last of the operation history stored in the memory, the last quitting of operation of the processor 62 is determined to be abnormal.

If the last quitting of operation of the processor 62 is abnormal, the processor 62 performs the relay driving process 64 (see FIG. 3), and starts outputting the relay drive signal at a time point t7. Notably, if the last quitting of operation of the processor 62 is normal, the processor 62, before performing the relay driving process 64, performs some other processes necessary for the control on the power supply circuit 32. In other words, if the last quitting of operation of the processor 62 is abnormal, the processor 62 skips some processes to be performed at normal times, and starts outputting the relay drive signal early. A time T5 from the time point t6 to the time point t7 is a time necessary for the processor 62 to perform the initialization operation mentioned above, the abnormal quitting detection process 66, and the relay driving process 64. Afterwards, the processor 62 performs the crash determination process 68, and subsequently performs the discharge process 70 at a tithe point t8. The time T2 from the time point t7 to the time point t8 is a time necessary for the processor 62 to perform the crash determination process 68, as mentioned above.

As described above, during a period from the time point t4 at which the processor 62 quits outputting the relay drive signal to the time point t7 at which the processor 62 resumes outputting the relay drive signal, the holding circuit 92 maintains the relay circuit 80 in a driven state. In other words, the holding circuit 92 can hold the relay circuit 80 in a driven state at least for a time equal to the total of the times T3, T4, and T5. When the output voltage of the accessory battery 34 is recovered, electric power supply from the accessory battery 34 to the processor 62 can thereby be resumed without the need of the relay drive signal provided by the processor 62. As one example, in the present embodiment, the maximum values of the times T3, T4, and T5 are assumed to be 300 milliseconds, 80 milliseconds, and 120 milliseconds, respectively. Accordingly, the holding circuit 92 in the present embodiment is designed to be able to hold the relay circuit 80 in a driven state at least for 500 milliseconds or more after the processor 62 quits outputting the relay drive signal.

The power storage element 94 in the holding circuit 92 only has to store just enough electric power to temporarily hold the relay circuit 80 in a driven state. The electric power necessary to hold the relay circuit 80 in a driven state is smaller than the electric power necessary to maintain the operation of the processor 62. For example, it is also contemplated that the processor 62 is provided with a back-up power source so as to prevent unintentional quitting of operation of the processor 62. However, the back-up power source for the processor 62 needs to have a capability to store much electric power, resulting in an increase in physical size of the back-up power source. When compared with such a back-up power source, the power storage element 94 in the holding circuit 92 has a small size. Accordingly, the holding circuit 92 can be provided within the motor control unit 44 without increasing the size of the motor control unit 44.

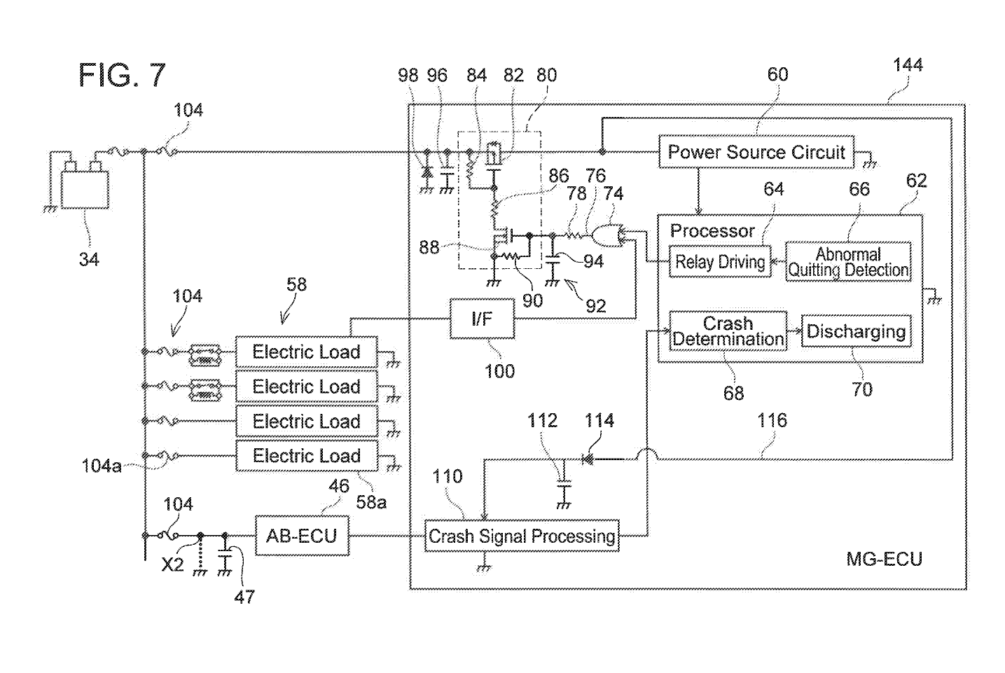

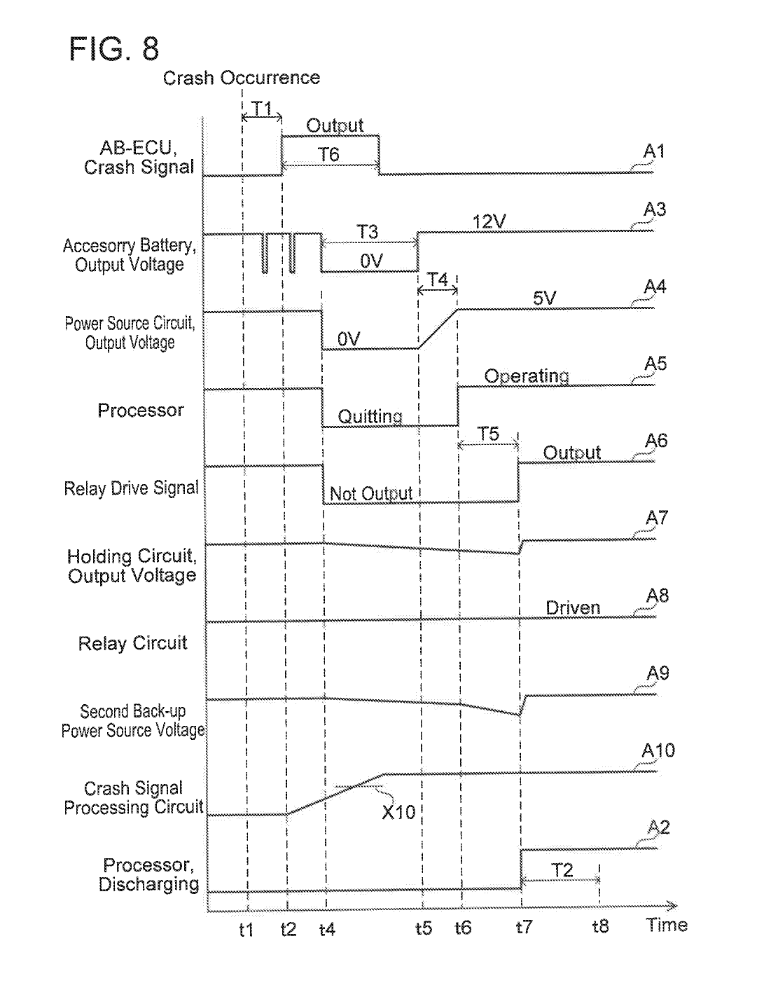

Next, with reference to FIGS. 7 and 8, a motor control unit 144 in a variation will be described. As shown in FIG. 7, the motor control unit 144 may further include a crash signal processing device 110 and a second back-up power source 112. The crash signal processing device 110 receives the crash signal from the air bag control unit 46, and outputs a second crash signal in accordance with the received crash signal to the processor 62. As one example, the crash signal processing device 110 herein described counts the number of the received pulse signals, and when the count value of the pulse signals reaches a prescribed threshold value, outputs the second crash signal to the processor 62. The crash signal processing device 110 is connected to the accessory battery 34 via a diode 114, and operates by the electric power from the accessory battery 34.

The second back-up power source 112 has a rechargeable power storage element (e.g., a capacitor or a secondary battery). The second back-up power source 112 is electrically connected to the accessory battery 34 via an electric power line 116 that has the diode 114, and is charged with the electric power from the accessory battery 34. When the electric power supply from the accessory battery 34 to the crash signal processing device 110 is stopped, the second back-up power source 112 substitutes for the accessory battery 34 and supplies electric power to the crash signal processing device 110. This enables the crash signal processing device 110 to continue its operation even if the output voltage of the accessory battery 34 temporarily decreases, for example.

As shown in FIG. 7, assume that a wire harness X2 that electrically connects the accessory battery 34 and the air bag control unit 46 is damaged and brought into contact with the vehicle body 12, to thereby be electrically grounded. In this case, the fuse 104 between the accessory battery 34 and the air bag control unit 46 is blown, and electric power supply from the accessory battery 34 to the air bag control unit 46 is interrupted. The air bag control unit 46 is provided with the first backup power source 47, and hence even after the electric power supply from the accessory battery 34 is interrupted, the air bag control unit 46 can temporarily continue its operation. Accordingly, as shown by A1 in FIG. 8, the air bag control unit 46 can detect a crash and output a crash signal. However, the crash signal is outputted from. the air bag control unit 46 exclusively for a time T6, which is a limited time. Accordingly, if the crash signal from the air bag control unit 46 has already been interrupted when the processor 62 is activated again at the time point t6 and the initialization process is completed at the time point t7, the processor 62 can no longer receive the crash signal from the air bag control unit 46.

In view of the issues above, the motor control unit 144 shown in FIG. 7 is provided with the crash signal processing device 110 and the second back-up power source 112. As shown by A10 in FIG. 8, the crash signal processing device 110 counts pulse signals in the crash signal, which is a train of pulse signals, and when the count value thereof reaches a prescribed threshold value X10, starts outputting the second crash signal to the processor 62. Here, the crash signal processing device 110 can continue its operation by the electric power from the second back-up power source 112 even while the output voltage of the accessory battery 34 temporarily decreases (see A9 in the drawing). When the initialization process is completed at the time point t7, the processor 62 can determine the presence or absence of a crash of the hybrid vehicle 10, based on the second crash signal from the crash signal processing device 110. In this case, the processor 62 only has to determine the presence or absence of the second crash signal in the crash determination process 68, and the time necessary for the crash determination process 68 becomes extremely short. The processor 62 can thereby start the discharge process 70 early immediately after the time point t7 (see A2 in FIG. 8).

As described above, according to the motor control unit 144 shown in FIG. 7, even if the crash signal from the air bag control unit 46 is interrupted, the processor 62 can perform the discharge process 70. Moreover, the crash determination as to the hybrid vehicle 10 is made by the crash determination process 68 independent of the processor 62, and hence the processor 62 can start and complete the discharge process 70 early.

The second back-up power source 112 only has to store just enough electric power to temporarily operate the crash signal processing device 110. The electric power necessary for the crash signal processing device 110 to operate is smaller than the electric power necessary for the processor 62 to operate. Accordingly, when compared with the back-up power source for the processor 62, mentioned above, the second back-up power source 112 is also decreased in size. Accordingly, the second back-up power source 112 can be provided within the motor control unit 144 without increasing the size of the motor control unit 144.

The configuration of the crash signal processing device 110 is not limited to the above-mentioned examples, and can be changed in accordance with a crash detection signal, for example. The crash signal processing device 110 does not necessarily need to make a crash determination as to the hybrid vehicle 10, and may also be configured to simply record the crash signal from the air bag control unit 46. In this case, after being activated again, the processor 62 can reference the crash signal recorded in the crash signal processing device 110. In other words, the crash signal processing device 110 outputs a part or a whole of the recorded crash signal to the processor 62 as the second crash signal in response to an instruction from the processor 62, for example. The processor 62 can perform the crash determination process 68 and the discharge process 70 based on the second crash signal from the crash signal processing device 110.

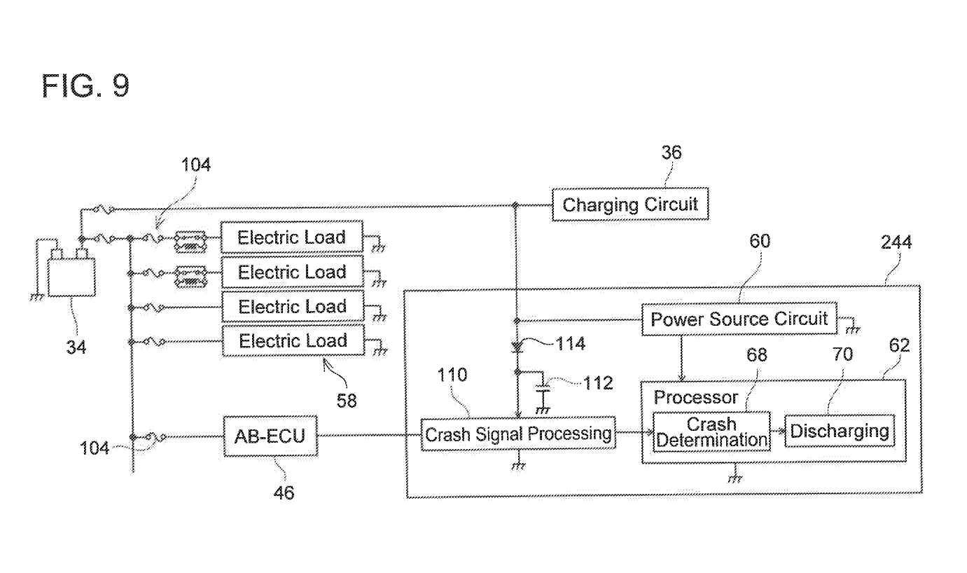

Next, with reference to FIG. 9, a motor control unit 244 in a variation will be described. In this variation as well, the motor control unit 244 includes the crash signal processing device 110 and the second back-up power source 112. The motor control unit 244, however, does not include the relay circuit 80, and the processor 62 is always electrically connected to the accessory battery 34 and the charging circuit 36. With such a configuration as well, when the output voltage of the accessory battery 34 decreases owing to a blowout of the fuse 104, there may be a case where the processor 62 temporarily quits its operation. Furthermore, if the blowout of the fuse 104 occurs between the accessory battery 34 and the air bag control unit 46, there may also be a case where the crash signal from the air bag control unit 46 has already been interrupted at the time point when the processor 62 completes the initialization process. However, after being activated again, the processor 62 can perform the crash determination process 68 and the discharge process 70 by referencing the crash signal recorded in the crash signal processing device 110. As such, the configuration according to the crash signal processing device 110 and the second back-up power source 112 can effectively function regardless of the presence or absence of the relay circuit 80.

Some specific examples have been described above in details. However, these are mere examples, and do not limit the scope of the claims. For example, the motor control units 44, 144, and 244, mentioned above, can be adopted not only in the hybrid vehicle 10, but also in various electric vehicles such as a rechargeable electric vehicle, a fuel cell vehicle, and a solar cell vehicle, for example. Notably, the accessory battery 34 in the embodiment is one example of the power source described in the claims. The air bag control unit 46 in the embodiment is one example of the crash detection device described in the claims. The second back-up power source 112 in the embodiment is one example of the back-up power source described in the claims.

The technical issues understood from the disclosure of the present specification will hereinafter be listed.

An electric vehicle (10) disclosed herein comprises: a motor (26) configured to drive a wheel (14); a smoothing capacitor (C1, C2) provided within a power supply circuit (32) that supplies electric power to the motor (26); a processor (62) configured to perform a discharge process (70) when the electric vehicle (10) crashes, the discharge process discharging the smoothing capacitor (C1, C2) by controlling the power supply circuit (32); a power source (34) connected to each of a plurality of electric loads (44, 46, 58, 62) including the processor (62) via a corresponding fuse (104); a relay circuit (80) electrically connected between the power source (34) and the processor (62) and configured to be driven to electrically connect between the power source (34) and the processor (62) in response to a relay drive signal outputted from the processor (62); and a holding circuit (92) configured to temporarily hold the relay circuit (80) in a driven state when the processor (62) quits outputting the relay drive signal. According to this configuration, the smoothing capacitor (C1, C2) within the power supply circuit (32) can be discharged reliably when the electric vehicle (10) crashes.

The holding circuit (92) may include a power storage element (94) configured to be charged by the relay drive signal outputted from the processor (62). According to such a configuration, the holding circuit (92) can drive the relay circuit (80) by electrical power charged within the power storage element (94).

If the relay drive signal has a prescribed DC voltage, the power storage element (94) in the holding circuit (92) may be connected in parallel with the processor (62) with respect to the relay circuit (80). According to such a configuration, the charged power storage element (94) can substitute for the processor (62) and output a signal equivalent to or corresponding to the relay drive signal.

At least one resistor (90) may be connected in parallel with the power storage element (94) in the holding circuit (92). According to such a configuration, after the output of the relay drive signal is quitted, the power storage element (94) is gradually discharged to thereby temporarily hold the relay circuit (80) in a driven state.

The electric vehicle (10) may further include: a crash detection device (46) configured to output a prescribed crash signal when the electric vehicle (10) crashes; a crash signal processing device (110) configured to receive the crash signal outputted from the crash detection device (46) and to output a second crash signal in accordance with the received crash signal to the processor (62); and a back-up power source (112) configured to supply electric power to the crash signal processing device (110) when electric power supply to the crash signal processing device (110) is interrupted. According to such a configuration, even when the crash signal from the crash detection device (46) is interrupted while the processor (62) temporarily quits its operation, the processor (62) can perform the discharge process (70) after being activated again, based on the second crash signal from the crash signal processing device (110).

The electric vehicle (10) may further include a main power source (30) configured to supply electric power to the motor (26) via the power supply circuit (32). The main power source (30) may be a rechargeable battery, a fuel cell, a solar cell, another electric power generating device, or a combination of at least two of them, for example.

What is claimed is:

1. An electric vehicle comprising:
a motor configured to drive a wheel;
a smoothing capacitor provided within a power supply circuit that supplies electric power to the motor;
a processor configured to perform a discharge process when the electric vehicle crashes, the discharge process discharging the smoothing capacitor by controlling the power supply circuit;
a power source connected to each of a plurality of electric loads including the processor via a corresponding fuse;
a relay circuit electrically connected between the power source and the processor and configured to be driven to electrically connect between the power source and the processor in response to a relay drive signal outputted from the processor; and
a holding circuit configured to temporarily hold the relay circuit in a driven state when the processor quits outputting the relay drive signal.

2. The electric vehicle according to claim 1, wherein the holding circuit comprises a power storage element configured to be charged by the relay drive signal outputted from the processor and is configured to drive the relay circuit by electric power charged within the power storage element.

3. The electric vehicle according to claim 2, wherein the relay drive signal is a signal having a DC voltage and the power storage element is connected in parallel with the processor with respect to the relay circuit.

4. The electric vehicle according to claim 3, wherein a resistor is connected in parallel with the power storage element.

5. The electric vehicle according to claim 1, further comprising:
a crash detection device configured to output a crash signal when the electric vehicle crashes;
a crash signal processing device configured to receive the crash signal outputted from the crash detection device and to output a second crash signal in accordance with the received crash signal to the processor; and
a back-up power source configured to supply electric power to the crash signal processing device when electric power supply to the crash signal processing device is interrupted.
